(19) United States
(12) Patent Application Publication
(10) Pub. No.: US 2010/0025861 A1
(43) Pub. Date: Feb. 4, 2010

(54) Hybrid-Level Three-Dimensional Mask-Programmable Read-Only Memory

(76) Inventor: Guobiao ZHANG, Corvallis, OR (US)

Correspondence Address: GUOBIAO ZHANG, P.O. BOX 6182, STATELINE, NV, 89449-6182, US

(21) Appl. No.: 12/476,263

(22) Filed: Jun. 2, 2009

Related U.S. Application Data
(63) Continuation-in-part of application No. 11/736,767, filed on Apr. 18, 2007, now abandoned.

(30) Foreign Application Priority Data
Dec. 1, 2006 (CN) 200610162698.2

(51) Int. Cl. H01L 27/06

(52) U.S. Cl. 257/777; 257/E27.026

(57) ABSTRACT

A hybrid-level three-dimensional mask-programmable read-only memory (HL-3DMPROM) includes a plurality of memory sets. Within each memory set, a plurality of vertically stacked memory levels are interleaved and all adjacent memory levels share address-selection lines; between adjacent memory sets, memory levels are separated by an inter-level dielectric and do not share any address-selection lines.

### CROSS-REFERENCE TO RELATED APPLICATIONS

This application is a continuation-in-part of U.S. patent application Ser. No. 11/736,767, filed Apr. 18, 2007, which is related to a CHINA P. R., Patent Application 200610162698.2, filed Dec. 1, 2006.

### BACKGROUND

1. Technical Field of the Invention

The present invention relates to the field of integrated circuit, and more particularly to mask-programmable read-only memory.

2. Related Arts

Mask-programmable read-only memory refers to those types of memories into which data are written during the manufacturing process, more particularly through pattern transfer. Among all kinds of mask-programmable read-only memories, three-dimensional mask-programmable read-only memory (3D-MPROM) has an extremely large capacity and low cost.

U.S. Pat. No. 5,835,396, issued to Zhang on Nov. 10, 1998, describes a typical 3D-MPROM. As illustrated in FIG. 1, a 3D-MPROM typically comprises a semiconductor substrate 0s and a 3D-MPROM stack 0, which is stacked above the substrate 0s. Transistors are built in the semiconductor substrate 0s using standard technology. These transistors provide means to address/read memory cells in the 3D-MPROM stack 0. The 3D-MPROM stack 0 comprises m vertically stacked memory levels (ML), where m is the total number of memory levels. In this example, m=2, which means the 3D-MPROM stack 0 has two memory levels: 100 and 200. These memory levels 100, 200 are laid down parallel to the substrate 0s, i.e. in the x-y plane and the memory level 200 is stacked above the memory level 100, i.e. along the z direction. Each memory level comprises a plurality of address-selection lines and memory cells. For example, the memory level 100 comprises word lines 30a, 30b . . . ; bit lines 20a, 20b . . . ; and memory cell 1aa, 1ab, 1bb, 1ba . . . . The word lines 30a, 30b . . . form an address-selection level, and the bit lines 20a, 20b . . . form another address-selection level. Apparently, these address-selection levels are parallel to the substrate 0s, i.e. in the x-y plane. Contact vias (e.g. 20av) couple memory levels (e.g. 100) to the transistors in the substrate 0s.

The prior-art 3D-MPROM takes the form of interleaved 3D-MPROM and separated 3D-MPROM. In an interleaved 3D-MPROM, all adjacent memory levels are interleaved, i.e. they share address-selection lines; in a separated 3D-MPROM, all adjacent memory levels are separated by an inter-level dielectric, i.e. they do not share address-selection lines. Examples of interleaved 3D-MPROM are illustrated in FIGS. 9A and 10A of U.S. Pat. No. 6,717,222, issued to Zhang on Apr. 6, 2004; and examples of separated 3D-MPROM are illustrated in FIGS. 9C and 10D of the same U.S. Pat. No. 6,717,222.

FIG. 2 illustrates a prior-art interleaved 3D-MPROM. It comprises a substrate 0s and a 3D-MPROM stack 0. The 3D-MPROM stack 0 comprises four memory levels 100-400. Each memory level (e.g. 400) comprises a plurality of word lines (e.g. 30a′, 30b′), bit lines (e.g. 20a″) and memory cells (e.g. 1a″a′, 1a″b′). Memory cells are located at the intersections between word lines and bit lines. Each memory cell further comprises a diode 25. It could be a junction diode (e.g. p-n diode, or p-i-n diode), or a Schottky diode. A config-dielectric 23 covers the diode 25. Depending on the existence or absence of an info-opening 27 in the config-dielectric 23, the memory cell represents different logic states (e.g. logic “1” or logic “0”). Memory levels (e.g. 400) are coupled to the substrate 0s through contact vias (e.g. 20av″).

In the interleaved 3D-MPROM, all adjacent memory levels share address-selection lines. For example, the memory levels 100 and 200 share word lines 30a, 30b . . . , which form the address-selection level 30L; the memory levels 200 and 300 share bit lines 20a′ . . . , which form the address-selection level 20L′; the memory levels 300 and 400 share word lines 30a′, 30b′ . . . , which form the address-selection level 30L′. Because all memory levels are interleaved (or, electrically coupled), reading of any single memory level (e.g. 100) involves leakage contributed by all other memory levels (e.g. 200-400). When the number of the memory levels is large (e.g. m>4), leakage becomes too large to be tolerated. To control leakage, the number of the memory levels in the interleaved 3D-MPROM should be limited (e.g. m≦4). This, in turn, limits the storage capacity of the interleaved 3D-MPROM.

FIG. 3 illustrates a prior-art separated 3D-MPROM. Its 3D-MPROM stack 0 comprises four memory levels 100-400. Different from the interleaved 3D-MPROM, all adjacent memory levels in the separated 3D-MPROM do not share any address-selection lines. To be more specific, the memory level 200 is separated from the memory level 100 by an inter-level dielectric 29a; the memory level 300 is separated from the memory level 200 by an inter-level dielectric 29b; and the memory level 400 is separated from the memory level 300 by an inter-level dielectric 29c. Because all memory levels are separated (or, electrically isolated), reading of one memory level (e.g. 100) does not involve leakage from other memory levels (e.g. 200-400). Accordingly, the separated 3D-MPROM is a preferred structure when 3D-MPROM has a large number of the memory levels (e.g. m≧4).

However, because no address-selection lines are shared, to construct the same memory levels, the separated 3D-MPROM needs more address-selection levels than the interleaved 3D-MPROM. For example, for a 3D-MPROM with four memory levels (i.e. m=4), the separated 3D-MPROM needs eight address-selection levels: 30L, 20L, 30L′, 20L′, 30L″, 20L″, 30L″′, and 20L″′ (FIG. 3), whereas the interleaved 3D-MPROM needs only five address-selection levels: 20L, 30L, 20L′, 30L′, and 20L″ (FIG. 2). In general, a separated 3D-MPROM with m memory levels needs 2m address-selection levels. Finished wafer cost rises with the number of address-selection levels. To lower the manufacturing cost, it is desirable to minimize the number of address-selection levels for a given storage capacity.

### OBJECTS AND ADVANTAGES

It is a principle object of the present invention to provide a three-dimensional mask-programmable read-only memory (3D-MPROM) with a large storage capacity and low manufacturing cost.

It is a further object of the present invention to minimize the manufacturing cost of the 3D-MPROM while maximizing the storage capacity.

In accordance with these and other objects of the present invention, a hybrid-level three-dimensional mask-programmable read-only memory (HL-3DMPROM) is disclosed.

### SUMMARY OF THE INVENTION

Different from the prior-art 3D-MPROMs, a hybrid-level three-dimensional mask-programmable read-only memory (HL-3DMPROM) comprises both interleaved and separated memory levels. Its 3D-MPROM stack comprises a plurality of 3D-MPROM sets. Within each 3D-MPROM set, memory levels are interleaved and all adjacent memory levels share address-selection lines; between adjacent 3D-MPROM sets, memory levels are separated by an inter-level dielectric and do not share any address-selection lines. This can be further described as follows: each memory level in the HL-3DMPROM shares at least one address-selection line with at least one adjacent memory level (note that, except for the lowermost and uppermost levels, each memory level has two adjacent levels, one immediately above and one immediately below), and at least one memory level does not share any address-selection lines with one adjacent memory level. Here, the term “adjacent” means “immediately above” or “immediately below”.

HL-3DMPROM combines the strengths of the interleaved and separated 3D-MPROM: the interleaved structure lowers the manufacturing cost of each 3D-MPROM set, while the separated structure enables a large number of memory levels (e.g. m≧4) and therefore, increases the overall storage capacity.

The preceding paragraphs have been provided by way of general introduction, and they are not intended to narrow the scope of the following claims.

### BRIEF DESCRIPTION OF THE DRAWINGS

FIG. 1 is a perspective view of a prior-art three-dimensional mask-programmable read-only memory (3D-MPROM);

FIG. 2 is a cross-sectional view of a prior-art interleaved 3D-MPROM;

FIG. 3 is a cross-sectional view of a prior-art separated 3D-MPROM;

FIG. 4 is a cross-sectional view of a preferred 2+2 HL-3DMPROM;

FIG. 5 is a cross-sectional view of a preferred 4+4 HL-3DMPROM;

FIG. 6 is a cross-sectional view of a preferred 2+4 HL-3DMPROM.

### DETAILED DESCRIPTION OF THE PREFERRED EMBODIMENTS

Those of ordinary skills in the art will realize that the following description of the present invention is illustrative only and is not intended to be in any way limiting. Other embodiments of the invention will readily suggest themselves to such skilled persons from an examination of the within disclosure.

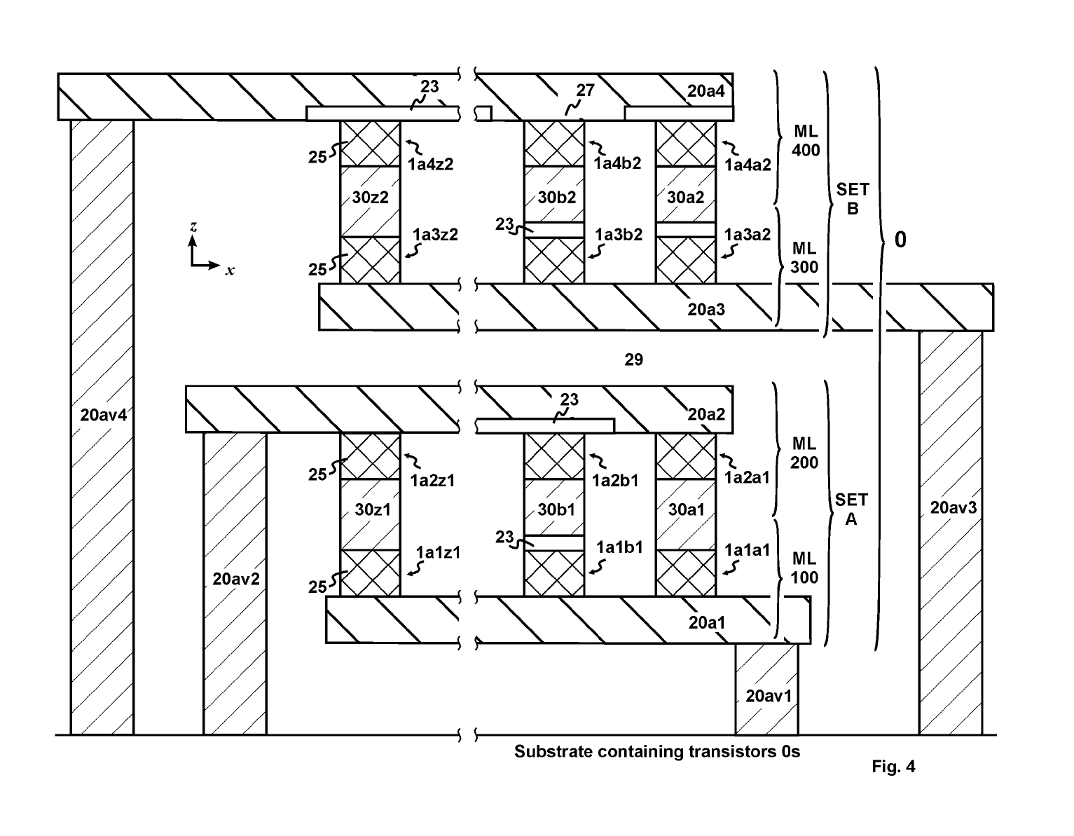

Referring now to FIG. 4, a preferred embodiment of a 2+2 HL-3DMPROM is disclosed. This preferred HL-3DMPROM comprises a semiconductor substrate 0s and a 3D-MPROM stack 0. The semiconductor substrate 0s comprises a plurality of transistors and the 3D-MPROM stack 0 comprises a plurality of memory levels 100-400. Transistors in the substrate 0s form peripheral circuits. These peripheral circuits perform addressing/read function for the memory levels 100-400. Contact vias 20av1-20av4 couple the memory levels 100-400 to the peripheral circuits in the substrate 0s. These contact vias can be located on two sides of the memory levels, or on one side of the memory levels.

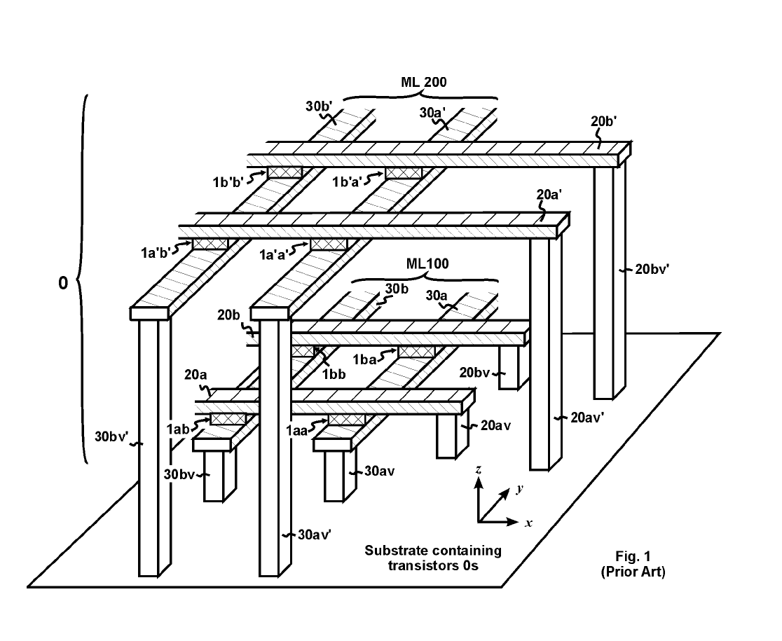

This preferred HL-3DMPROM has four memory levels 100-400 (i.e. m=4). These memory levels are laid down parallel to the substrate 0s, i.e. in the x-y plane (y direction is perpendicular to the sheet, as in FIG. 1) and are vertically stacked, i.e. along the z direction. Each memory level comprises a plurality of address-selection lines and memory cells. The address-selection lines along the y direction (e.g. 30a1-30z1, 30a2-30z2) are referred as word lines. The address-selection lines along the x direction (e.g. 20a1, 20a2, 20a3, 20a4) are referred as bit lines. The memory cells (e.g. 1a1a1-1a1z1, 1a2a1-1a2z1, 1a3a2-1a3z2, 1a4a2-1a4z2) comprise two terminal devices 25, which provide a coupling mechanism between word lines and the bit lines. The coupling mechanism includes resistive, capacitive, inductive, diode, or active device elements. A commonly used coupling mechanism is diode. A diode could be a junction diode (e.g. p-n diode, or p-i-n diode), or a Schottky diode. A config-dielectric 23 covers the diode 25. If there is an info-opening 27 in the config-dielectric 23, the memory cell (e.g. 1a4b2) represents logic “1”; otherwise, the memory cell (e.g. 1a4a2) represents logic “0”. Besides binary logic, 3D-MPROM can also represent N-ary logic (N>2).

Further details on various aspects of 3D-MPROM are disclosed in Zhang, U.S. Pat. No. 5,835,396, “Three-Dimensional Read-Only Memory”; Johnson, U.S. Pat. No. 6,624,485, “Three-Dimensional Mask-Programmed Read Only Memory”; Zhang, U.S. Pat. No. 6,717,222, “Three-Dimensional Memory”; Zhang, U.S. Pat. No. 6,903,427, “Mask Programmable Read Only Memory Based on nF-Opening Mask”; Zhang, U.S. Pat. No. 7,386,652, “User-Configurable Pre-Recorded Memory”; Zhang, U.S. patent application Ser. No. 11/162,262, “N-ary Mask Programmable Memory”, filed on Sep. 2, 2005 and others.

In this preferred embodiment, four memory levels are divided into two 3D-MPROM sets: Set A and Set B. Set A consists of memory levels 100 and 200; Set B consists of memory levels 300 and 400. Within each 3D-MPROM set, memory levels are interleaved and all adjacent memory levels share address-selection lines; between adjacent 3D-MPROM sets, memory levels are separated by an inter-level dielectric and do not share any address-selection lines. Here, the term “adjacent” means “immediately above” or “immediately below”. To be more specific, in Set A, the memory levels 100 and 200 share the word lines 30a1-30z1 . . . ; in Set B, the memory levels 300 and 400 share the word lines 30a2-30z2 . . . ; the memory level 200 in Set A and the memory levels 300 in Set B are separated by the inter-level dielectric 29 and do not share any address-selection lines.

The preferred embodiment in FIG. 4 can be further described as follows: each memory level shares at least one address-selection line with at least one adjacent memory level (note that, except for the lowermost and uppermost levels, each memory level has two adjacent levels, one immediately above and one immediately below), and at least one memory level does not share any address-selection lines with one adjacent memory level. To be more specific, the memory levels 100 and 200 share the word lines 30a1-30z1 with each other; the memory levels 300 and 400 shares the word lines 30a2-30z2 with each other. However, the memory levels 200 and 300 do not share any address-selection lines.

The present invention uses the following convention “a+b HL-3DMPROM” to denote an HL-3DMPROM with two 3D-MPROM sets—the first 3D-MPROM set has a number of memory levels, and the second 3D-MPROM set has b number of memory levels, with the second 3D-MPROM set stacked above the first 3D-MPROM set. Likewise, a+b+c HL-3DMPROM denotes an HL-3DMPROM with three 3D-MPROM sets, and so on. According to this convention, the preferred embodiment in FIG. 4 is a 2+2 HL-3DMPROM.

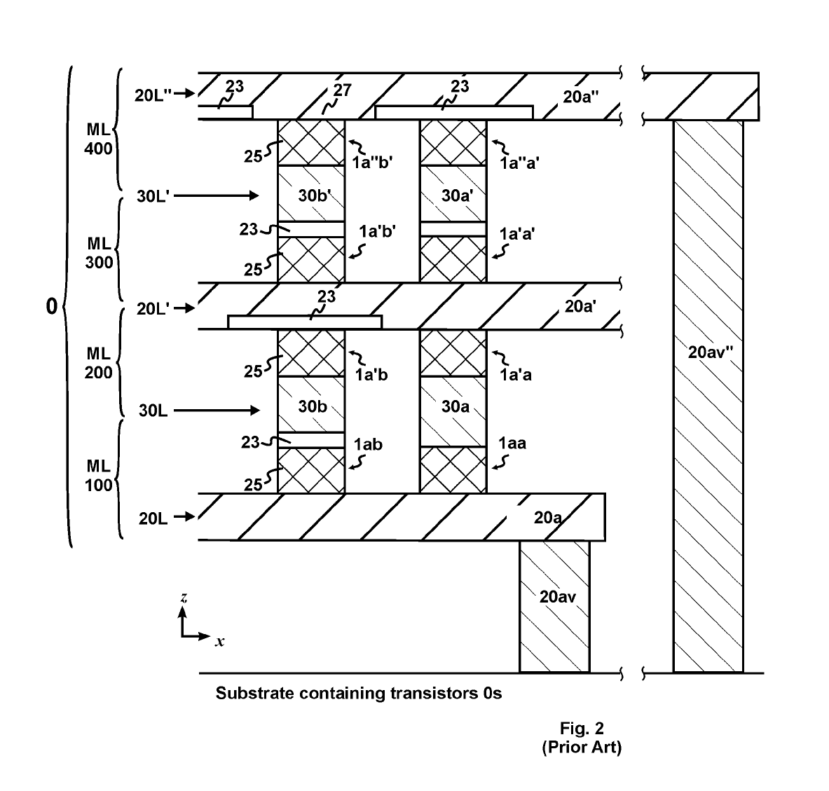

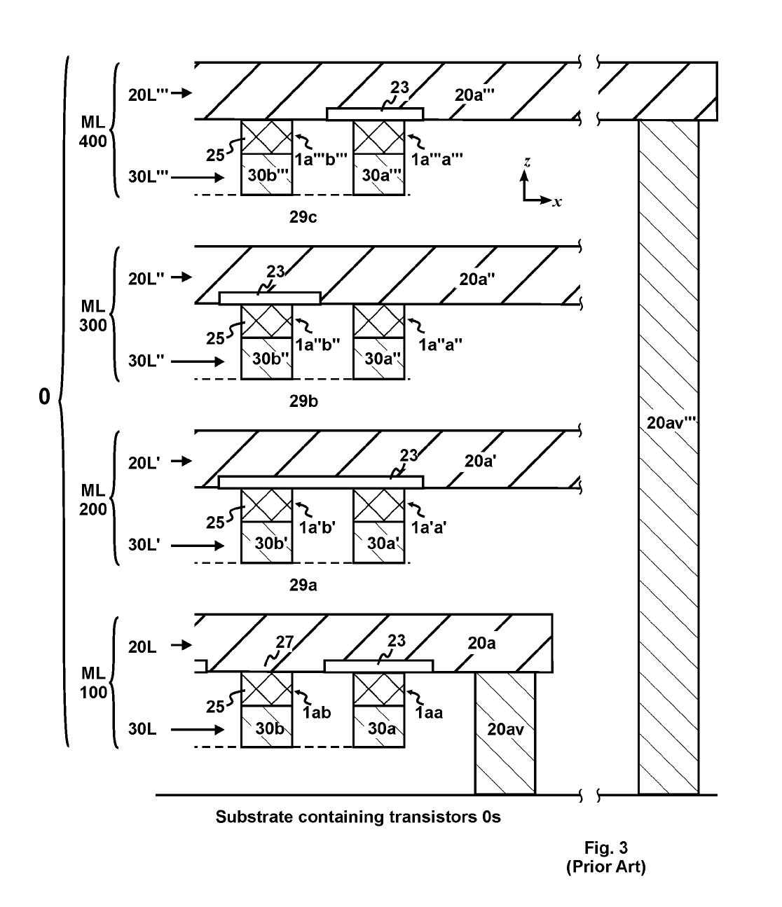

HL-3DMPROM is advantageous over the prior-art 3D-MPROM in two ways: A) by interleaving memory levels within a 3D-MPROM set, the total number of address-selection levels is reduced. In this preferred embodiment, the total number of address-selection levels is six, less than the prior-art separated 3D-MPROM of FIG. 3, which requires eight. This leads to a lower manufacturing cost; B) by separating (i.e. electrically isolating) memory levels from different 3D-MPROM sets, leakage during read only comes from the memory levels within the same 3D-MPROM set. For example, when reading the memory level 100, only the memory level 200 contributes to leakage. In contrast, for the prior-art interleaved 3D-MPROM of FIG. 2, all memory levels 100-400 contribute to leakage and therefore, leakage scales with the total number of memory levels. For HL-3DMPROM, because leakage does not scale with the total number of memory levels, more memory levels can be stacked and this leads to a larger storage capacity.

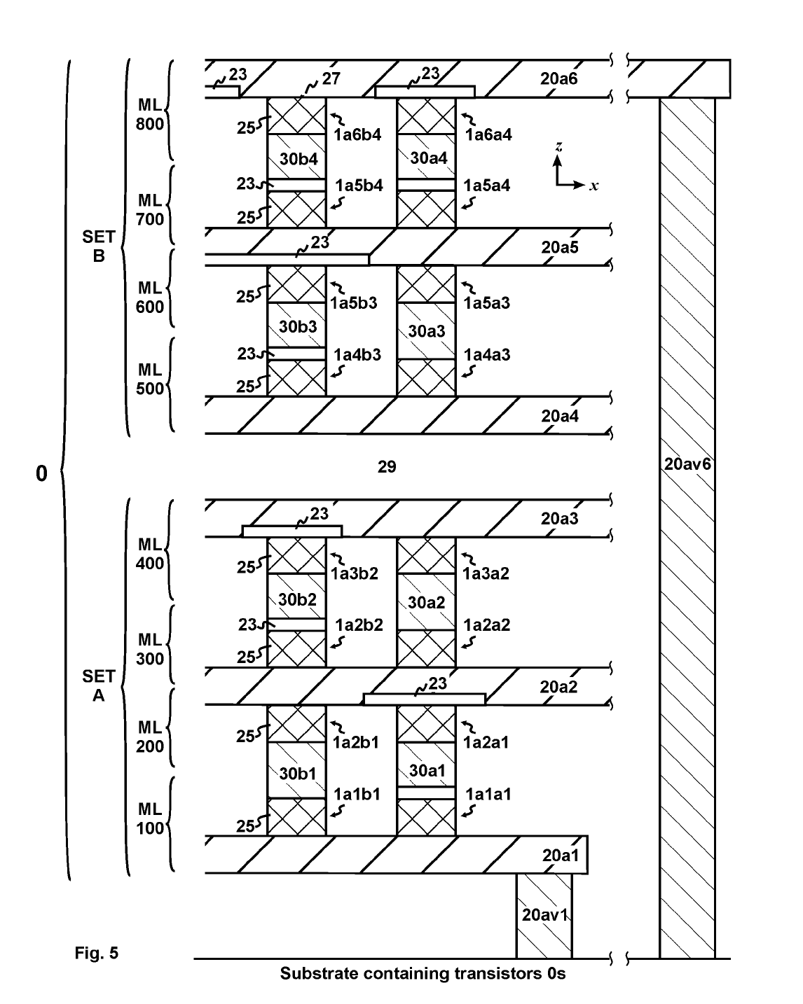

Referring now to FIG. 5, a preferred HL-3DMPROMs with eight memory levels (i.e. m=8) is disclosed. The preferred embodiment of FIG. 5 is a 4+4 HL-3DMPROM. Its memory levels 100-800 are divided into two 3D-MPROM sets: Set A and Set B. Set A consists of four interleaved memory levels 100-400; Set B consists of four interleaved memory levels 500-800. Within each set, all adjacent memory levels share address-selection lines. In Set A, the memory levels 100 and 200 share word lines 30a1, 30b1 . . . ; the memory levels 200 and 300 share bit lines 20a2 . . . ; the memory levels 300 and 400 share word lines 30a2, 30b2 . . . . In Set B, the memory levels 500 and 600 share word lines 30a3, 30b3 . . . ; the memory levels 600 and 700 share bit lines 20a5 . . . ; the memory levels 700 and 800 share word lines 30a4, 30b4 . . . . The memory levels 20a3 in Set A and the memory level 20a4 in Set B are separated by an inter-level dielectric 29 and do not share any address-selection lines. In sum, this particular HL-3DMPROM embodiment needs ten address-selection levels, considerably less than the prior-art separated 3D-MPROM, which needs sixteen address-selection levels.

Alternatively, for eight memory levels, a 2+2+2+2 HL-3DMPROM can be formed. Its memory levels are divided into four 3D-MPROM sets. Each set consists of two interleaved memory levels, and is separated from adjacent set by an inter-level dielectric. This particular HL-3DMPROM embodiment needs twelve address-selection levels, considerably less than the prior-art separated 3D-MPROM, which needs sixteen address-selection levels.

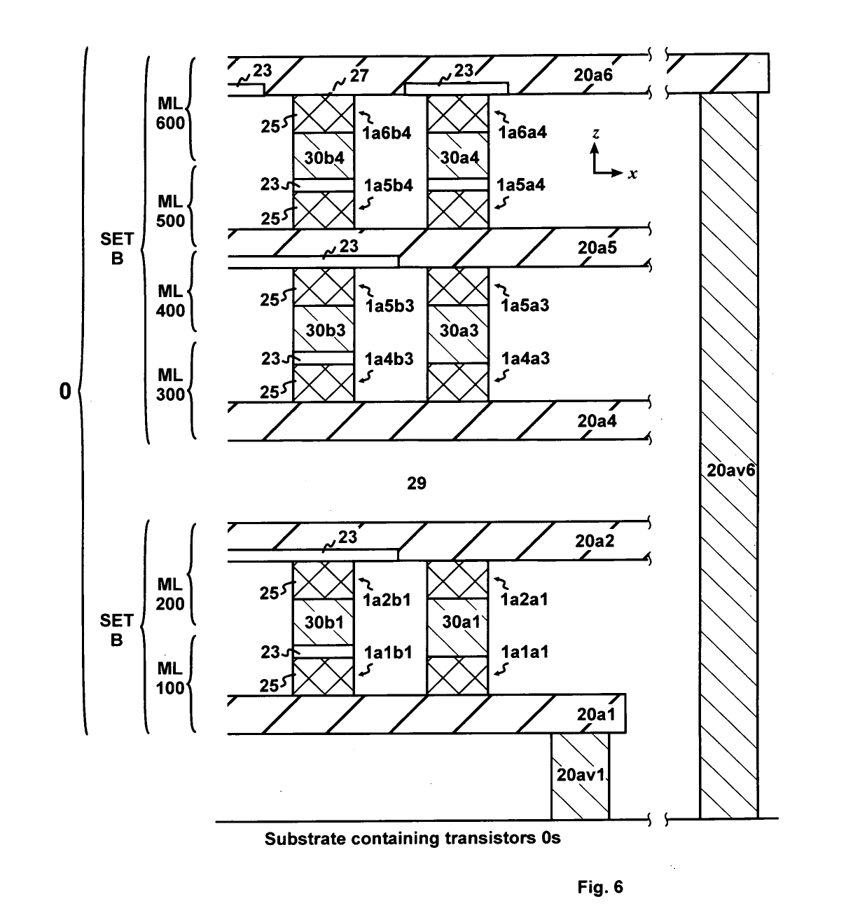

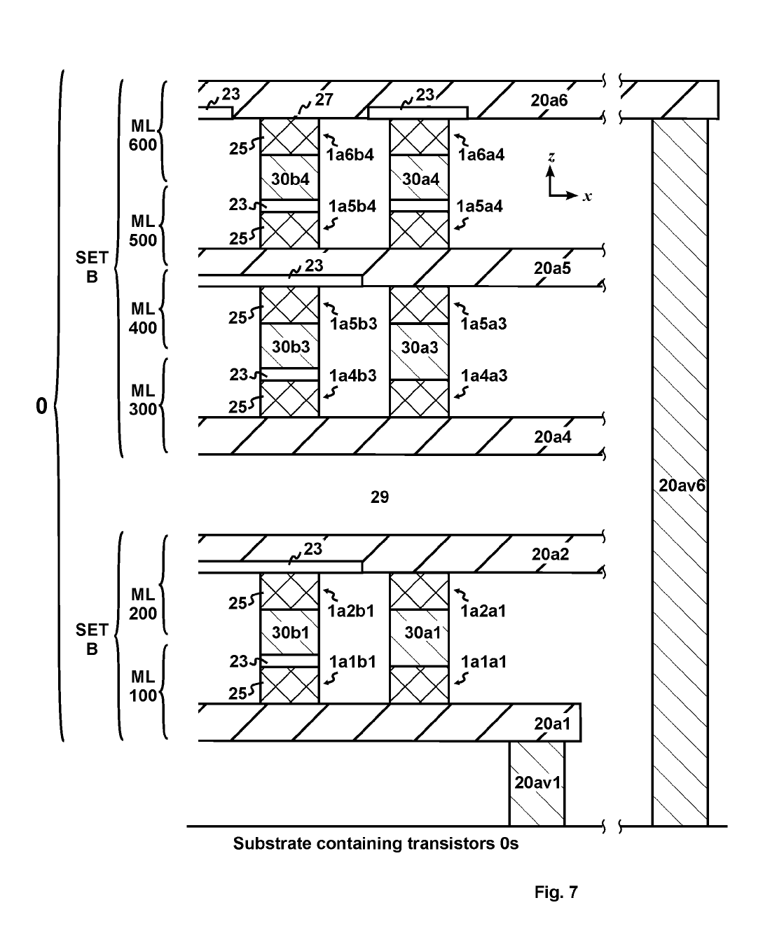

Referring now to FIG. 6, a preferred 2+4 HL-3DMPROM is disclosed. It comprise two 3D-MPROM sets A and B. Different from previous preferred embodiments where each set has the same number of memory levels, Sets A and B in this preferred embodiment consist of different number of memory levels. To be more specific, Set A consists of two interleaved memory levels, i.e. memory levels 100 and 200; whereas, Set B consists of four interleaved memory levels, i.e. memory levels 300-600. Sets A and B are separated by an inter-level dielectric 29.

While illustrative embodiments have been shown and described, it would be apparent to those skilled in the art that may more modifications than that have been mentioned above are possible without departing from the inventive concepts set forth therein. For example, the preferred HL-3DMPROM may comprise active devices such as transistors (e.g. thin-film transistors). Moreover, m could be larger than 8, e.g. it could be 12, 16 . . . . The invention, therefore, is not to be limited except in the spirit of the appended claims.

What is claimed is:

1. A hybrid-level three-dimensional mask-programmable read-only memory (HL-3DMPROM), comprising:
a substrate including transistors;
a first mask-programmable read-only memory level above said substrate and coupled to said substrate;
a second mask-programmable read-only memory level above said first memory level and coupled to said substrate, said first and second memory levels sharing at least one address-selection line;
an inter-level dielectric above said second memory level;
a third mask-programmable read-only memory level above said inter-level dielectric and coupled to said substrate;
a fourth mask-programmable read-only memory level above said third memory level and coupled to said substrate, said third and fourth memory levels sharing at least one address-selection line.

2. The HL-3DMPROM according to claim 1, wherein the total number of memory levels in said HL-3DMPROM is no less than 4.

3. The HL-3DMPROM according to claim 1, wherein at least one of said first, second, third and fourth memory levels comprises passive devices.

4. The HL-3DMPROM according to claim 3, wherein said passive devices comprise diodes.

5. The HL-3DMPROM according to claim 4, wherein said diodes are junction diodes.

6. The HL-3DMPROM according to claim 4, wherein said diodes are Schottky diodes.

7. The HL-3DMPROM according to claim 1, wherein at least one of said first, second, third and fourth memory levels comprises active devices.

8. A hybrid-level three-dimensional mask-programmable read-only memory (HL-3DMPROM), comprising:
a substrate including transistors;
a plurality of vertically stacked mask-programmable read-only memory levels above said substrate and coupled to said substrate;
wherein each of said memory levels shares at least one address-selection line with at least one adjacent memory level, and at least a selected one of said memory levels does not share any address-selection lines with one adjacent memory level.

9. The HL-3DMPROM according to claim 8, wherein said selected memory level is separated from one adjacent memory level by an inter-level dielectric.

10. The HL-3DMPROM according to claim 8, wherein the total number of memory levels in said HL-3DMPROM is no less than 4.

11. The HL-3DMPROM according to claim 8, wherein said memory levels comprise passive devices.

12. The HL-3DMPROM according to claim 11, wherein said passive devices comprise diodes.

13. The HL-3DMPROM according to claim 8, wherein said memory levels comprises active devices.

14. A hybrid-level three-dimensional mask-programmable read-only memory (HL-3DMPROM), comprising:
a substrate including transistors;
a first 3D-MPROM set above said substrate and coupled to said substrate;
an inter-level dielectric above said first 3D-MPROM set;
a second 3D-MPROM set above said inter-level dielectric and coupled to said substrate;
wherein each of said first and second 3D-MPROM sets comprises a plurality of vertically stacked and interleaved mask-programmable read-only memory levels, and all adjacent memory levels in each of said first and second 3D-MPROM sets share address-selection lines.

15. The HL-3DMPROM according to claim 14, wherein the total number of memory levels in said HL-3DMPROM is no less than 4.

16. The HL-3DMPROM according to claim 14, wherein said memory levels comprise passive devices.

17. The HL-3DMPROM according to claim 16, wherein said passive devices comprise diodes.

18. The HL-3DMPROM according to claim 14, wherein said memory levels comprises active devices.

19. The HL-3DMPROM according to claim 14, wherein said first and second 3D-MPROM sets comprise same number of memory levels.

20. The HL-3DMPROM according to claim 14, wherein said first and second 3D-MPROM sets comprise different number of memory levels.
